(19) United States
(12) Patent Application Publication
(10) Pub. No.: US 2007/0042910 A1
(43) Pub. Date: Feb. 22, 2007

(54) Method of manufacturing an electrically insulating and mechanically structuring sheath on an electrical condutor

(75) Inventors: Alexandre Puigsegur, Perpignan (FR); Francoise Rondeaux, Issy la Noulineaux (FR); Eric Prouzet, Montpellia (FR)

Correspondence Address: MCKENNA LONG & ALDRIDGE LLP, 1900 K STREET, NW, WASHINGTON, DC, 20006, US

(73) Assignees: COMMISSARIAT A L'ENERGIE ATOMIQUE, PARIS (FR); CENTRE NATIONAL DE LA RECHERCHE SCIENTIFIQUE, PARIS (FR)

(21) Appl. No.: 10/557,407

(22) PCT Filed: May 18, 2004
(86) PCT No.: PCT/FR04/50200

§ 371 Date: Jul. 21, 2006

(30) Foreign Application Priority Data
May 19, 2003 (FR) 03/050158

(51) Int. Cl. H01L 39/24

(52) U.S. Cl. 505/100

(57) ABSTRACT

This invention applies in particular to the manufacture of superconducting magnets. A ceramic precursor in the form of a fluid solution is formed, said ceramic precursor being a liquid consisting of a solution comprising water, glass frit and a suspension of clay in water, without any organic element, then a coating for the conductor is formed with said precursor and said coating is heat-treated in order to form the ceramic.

### TECHNICAL FIELD

This invention relates to a method of manufacturing an electrically insulating and mechanically structuring sheath on an electrical conductor.

The invention makes it possible to obtain an electrically insulated conductor that can be used within a wide range of temperatures and, more particularly, at very low temperatures less than or equal to 4.2 K, corresponding to the field of exploitation of superconducting magnets used to produce strong magnetic fields.

The invention is thereby especially applicable to the manufacture of such superconducting magnets.

It is also applicable to the manufacture of pole pieces for electric motors.

### STATE OF THE PRIOR ART

Superconducting electromagnets made of Nb₃Sn type alloys are already known. Such alloys are capable of producing intense magnetic fields as high as 24 teslas, which gives them a definite advantage over the NbTi type alloys commonly used in such electromagnets.

However, the characteristics of Nb₃Sn make it difficult to use because, unlike NbTi, which is a very ductile and easily extruded alloy, it is difficult to manufacture multifilamentary Nb₃Sn components.

As a matter of fact, Nb₃Sn is a polycrystalline intermetallic material which, in order to be formed, must undergo a long heat treatment possibly lasting as long as 3 weeks, at temperatures of 600° C. to 720° C. in an inert atmosphere. Once treated, it becomes brittle and its superconducting properties are very sensitive to any mechanical deformation.

Thus, when manufacturing an electromagnet from the Nb₃Sn alloy, it ends up being necessary to produce the winding of the electromagnet using a cable made with the aid of a “precursor” of this alloy, and to put it through a subsequent treatment, namely a temperature cycling treatment, enabling the formation of Nb₃Sn.

This treatment is also called a “reaction” throughout the remainder of the description, and the cable made using a Nb₃Sn precursor is called a “non-reacted cable”.

Placement of the cable's electrical insulation is particularly tricky because it is difficult to use a conventional organic-type material for this insulation. As a matter of fact, a material such as this does not withstand a heat treatment during the course of which the temperature exceeds 600° C.

Reference will be made to the following document:

WO 03/010781A, invention of Jean-Michel Rey, Sandrine Marchant, Arnaud Devred and Eric Prouzet.

This document discloses a method of manufacturing an electrically insulating and mechanically structuring sheath on an electrical conductor and proposes the use of a gelled solution containing an organic binder for depositing a ceramic precursor either directly on the conductor to be insulated or on a tape serving to surround this conductor.

However, the use of a gel necessitates the use of an acid in order to produce the gel. Furthermore, the presence of an organic binder is not desirable because it can lead to the creation of carbon residues that are harmful to the insulating properties of the ceramic. This undesirable effect thus necessitates a phase for eliminating the organic binder.

Reference will likewise be made to the following document:

U.S. Pat. No. 6,387,852 B, E. Celik, Y. Hascicek and I. Mutlu.

This document describes a method for covering superconductors with an electrical insulator. However, this method likewise uses a sol-gel solution requiring oxides and organic solvents, i.e., isopropanol and acetyl acetone, in order to form the ceramic precursor.

### DESCRIPTION OF THE INVENTION

The purpose of this invention is to remedy the preceding disadvantages.

No organic binder is used in the invention, and the suspension used in the formation of the ceramic precursor is not a gel but a fluid solution containing no organic element.

The method which is the object of the invention leads to a simplification of the compositions used for its implementation and to a clear separation between the production stages of the insulated conductor, as will later be seen.

More precisely, the object of the invention is a method for manufacturing an electrically insulating and mechanically structuring sheath on an electrical conductor, in particular a non-superconducting metal conductor, a superconducting metal conductor or a superconductor precursor conductor, this method being characterized in that it comprises the steps of:
forming a ceramic precursor in the form of a fluid solution, said ceramic precursor being a liquid consisting of a solution containing water, glass frit and a suspension of clay in water, without any organic element,
forming a coating for the conductor with said ceramic precursor, and
heat-treating said coating, said heat treatment being capable of forming the ceramic from the ceramic precursor.

More preferably, the clay is selected from the smectite group and, within this group, montmorillonite is preferably selected.

According to a preferred embodiment of the invention, the solution comprises, in percent by weight, 35% to 50% water, 8% to 15% clay and 35% to 55% glass frit.

According to a first particular mode of implementing the method which is the object of the invention, the conductor is made of a superconductor precursor, in particular Nb₃Sn, and a global heat treatment of said conductor provided with the coating is carried out, said global heat treatment being capable of forming the superconductor and the ceramic.

According to a second particular implementation mode, the conductor is made of either a non-superconducting metal or a superconducting metal, and a heat treatment of said conductor provided with the coating is carried out, said heat treatment being capable of forming the ceramic.

According to one particular embodiment of the invention, the step of forming the coating comprises a step of depositing the ceramic precursor on a fiber tape, then a step of arranging the tape provided with the ceramic precursor around the conductor.

In this case, the tape is coated with the ceramic precursor and the fibers may be made of a material selected from among type E glass, type C glass, type R glass, type S2 glass, pure silica, an alumina and an aluminosilicate.

More preferably, the fiber tape is first desized, e.g., thermally or chemically.

According to one particular mode of implementing the method which is the object of the invention, the conductor provided with the coating is formed prior to the heat treatment step capable of forming the ceramic.

To form the conductor, it is possible, for example, to wind said conductor (provided with the coating) prior to the heat treatment step capable of forming the ceramic.

### BRIEF DESCRIPTION OF THE DRAWINGS

This invention will be better understood upon reading the description of the exemplary embodiments provided below, for purely illustrative and non-limiting purposes, with reference to the appended drawings in which:

FIG. 1 is a schematic illustration of the steps of one particular mode of implementing the method which is the object of the invention,

FIG. 2 is a schematic illustration of one particular application of the invention, and

FIGS. 3 and 4 show consistency curves of ceramic suspensions having different compositions.

### DETAILED DESCRIPTION OF PARTICULAR EMBODIMENTS

The electrical insulation technique proposed by this invention makes it possible to deposit a ceramic sheathing on a non-reacted conductor cable (made of a Nb₃Sn precursor) prior to forming a superconducting magnet coil.

The ceramic sheathing will react simultaneously during the temperature cycling necessary to the formation of the Nb₃Sn superconductor, and will thereby contribute to the electrical insulation and mechanical cohesion of the coil (structuring function).

In order to facilitate industrial exploitation of the insulating method, the phases for preparing the ceramic precursor, for preparing the ceramic sheath (e.g., by coating a glass fiber tape) and for sheathing the conductor cable (wrapping) are distinct from one another.

The ceramic sheathing of the conductor must possess certain properties in order to guarantee proper functioning of the superconducting cable ultimately formed. This sheathing must:
ensure the electrical insulation of the conductor cable,
guarantee the mechanical cohesion of the coil resulting from the formation of the insulated conductor,
maintain an appropriate level of mechanical resistance within a range of temperatures from ambient temperature (approximately 300 K) to 1.6 K, and
if possible, have a certain degree of porosity so as to enable the diffusion of helium to the surface of the conductor, for applications relating to superconducting magnets.

In one example of the invention, the production of an electrically insulated Nb₃Sn superconductor cable is carried out in several very distinct phases, namely:
preparation of a suspension forming a ceramic precursor,
manufacture of a ceramic sheathing by coating a glass fiber tape with said suspension,
wrapping, by means of said tape, a conductor cable consisting of a non-reacted Nb₃Sn precursor,
formation of a coil using the thus wrapped conductor cable, and
successful completion of a temperature cycling operation necessary to the reaction of the Nb₃Sn precursor. This temperature cycling operation simultaneously converts the Nb₃Sn precursor into a superconductor and the ceramic precursor coating into ceramic.

In this way, a Nb₃Sn superconducting coil is obtained, which is electrically insulated and mechanically cohesive.

The preparation of a ceramic precursor is explained below.

The solution used by the invention to form this precursor has no organic component, in particular of the binder type, in order to prevent the formation of carbon residues that are known to be detrimental to proper electrical insulation.

This solution is preferably a ternary mixture of a montmorillonite-type clay, glass frit and water, which forms a ceramic suspension.

In one example, the montmorillonite used is produced by the company Arvel SA, under the trade name Expans.

This clay makes it possible to provide the necessary degree of plasticity to the impregnated tape that will be used during wrapping of the conductor cable (made of a precursor of the Nb₃Sn alloy). Moreover, it enables bending radiuses of the order of 2 mm for the sheathing tape.

Compared with other clays, its high plasticizing capacity makes it possible to reduce the amount used and to proportionally increase the amount of glass frit.

The glass frit used is manufactured by the Johnson & Mattey Company, under the reference number 2495F. Its melting point is 538° C.

The glass frit is a fusible element that adds to the cohesion of the ceramic insulation following the heat treatment.

The water makes it possible to adjust the viscosity of the suspension.

The rheological behavior of two particular compositions of the ceramic suspension is considered at the end of this description. As indicated, the experimental conditions are such that the flow rate involved is that described at the start of the behavior curves.

The clay and the glass frit are heated to 100° C. for 12 hours in an oven, in order to eliminate possible traces of moisture. Then, the two powders consisting of clay and glass frit are ground separately until a particle size of less than 20 μm is attained. The glass frit is then mixed with the water using a magnetic stirrer.

The solution resulting from this mixture is then subjected to the effects of a Vibracell 72412 model, Bioblock Scientific brand ultrasound gun, operated at 300-watt power. The purpose of this treatment is to break up possible aggregates of particles.

Next, the solution is left to agitate for 4 hours to enable stabilization of its pH value. This stabilization waiting period makes it possible to ensure the reproducibility of the experimental conditions when preparing the ceramic precursor.

The clay is then incorporated by successive additions, which facilitates the overall mixing operation, and then, the suspension obtained is again treated using the ultrasound gun, so as to obtain a homogenous mixture.

Experimental observations indicate that a gelation of the suspension is obtained.

This suspension is then stirred. To accomplish this, in the example described, it is placed on a roller stirrer for 12 hours, in a polyethylene flask containing approximately twenty porcelain balls measuring 20 mm in diameter. Owing to this stirring technique, proper homogenization of the solution is obtained and the suspension is given a fluid appearance.

For all practical purposes, the stirring disrupts the previously noted gelation process.

The reduced viscosity of the mixture is necessary for proper impregnation of the glass fiber tape that will be used for the sheathing of the conductor.

A volume of approximately 600 milliliters of mixture is made up for each preparation.

The composition matter of the suspension will now be disclosed.

In the ceramic precursor, the weight percentages may vary within the ranges provided below (the sum of the percentages having to be equal, of course, to 100% for a given ceramic precursor):

35% to 50% for the water,
35% to 55% for the glass frit, and
8% to 15% for the montmorillonite-type clay.

The manufacture of the ceramic sheathing is explained below.

In the example described, the ceramic sheath consists of a glass fiber tape that is impregnated with the ceramic suspension described above. The fibers of this tape may be made of type E, C, R or S2 glass. These fibers may likewise be made of pure silica, alumina or aluminosilicate.

Prior to being impregnated, the tape undergoes a heat treatment (it is maintained at 350° C. for 12 hours), in order to eliminate the organic sizing from the fibers with which it is made.

As a matter of fact, this sizing is detrimental to a proper coating of the fibers with the ceramic suspension and constitutes a source of carbon elements likely to reduce the insulating properties of the ceramic.

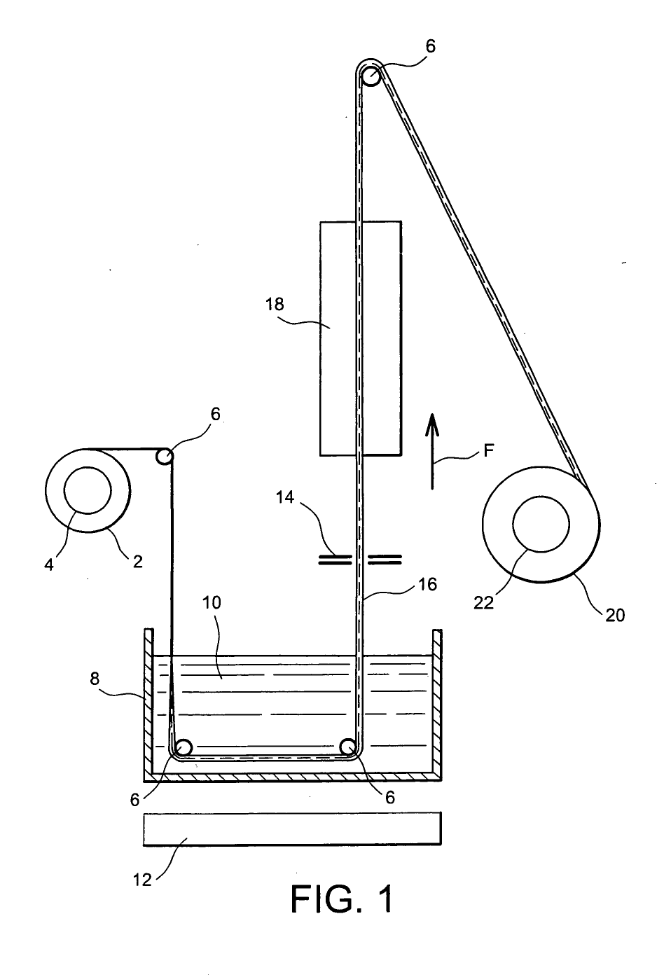

The coating of the glass fiber tape with the ceramic solution is carried out by an impregnation system shown schematically in FIG. 1.

The desized tape, in the form of a roll 2, is fastened to a brake system 4, which makes it possible to unroll the tape while at the same time maintaining a constant degree of tension. Pulleys 6 make it possible to guide the tape through the various components of the impregnation system. The direction of movement is indicated by the arrow F.

In a first phase, the tape passes into an impregnation tank 8 containing the ceramic suspension 10. The latter is stirred continuously, by means of a magnetic stirrer 12, during the impregnation phase of the tape, in order to preserve the evenness of said tape and to prevent sedimentation problems.

Upon exiting the tank 8, the tape 2 passes through a system of scrapers 14 which makes it possible to limit the thickness of the ceramic deposit 16 formed on the tape (due to its passage into the ceramic suspension).

A drying column 18, heated to 150° C., enables the water to evaporate completely from the ceramic solution deposited on the tape.

Upon exiting the column, the ceramic precursor sheath is completely dry. It is pre-processed in the form of a roll 20, by means of a motor 22, which maintains a constant rate of advance of 20 cm per minute.

The manufacture of a four-pole electromagnet according to the invention is described below, using the present invention.

The construction of an electromagnet such as this makes it necessary to manufacture four identical windings, each winding consisting of 75 m of a Rutherford-type superconductor cable.

Rutherford cables have an approximately trapezoidal cross-section and consist of 36 conductive strands that are twisted together and, in the example, ultimately made of Nb₃Sn.

These strands are distributed so as to form a flat, two-layer conductor whose cross section has the following approximate dimensions: 1.3 mm for the small side, 1.6 mm for the large side and 15.1 mm for the width.

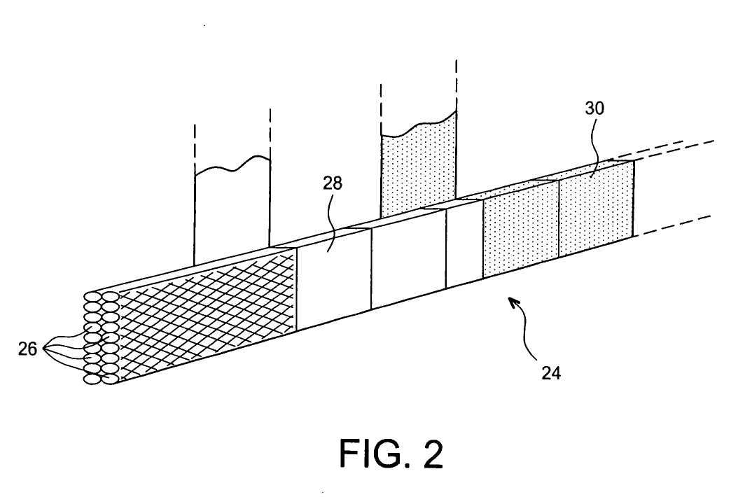

The ceramic sheathing, consisting of the glass fiber tape impregnated with the ceramic precursor, is wrapped around the Rutherford conductor cable (made of the Nb₃Sn precursor) in two layers, offset by a half-width, as seen in FIG. 2.

In this figure, the reference numbers 24, 26, 28 and 30 represent, respectively, the cable (prior to the treatment intended to form Nb₃Sn), the strands of the cable, the first layer of the tape and the second layer of the tape.

For each of these layers, the edge of one turn of tape is situated against the edge of the adjacent turn. In addition, the first layer 28 is positioned first on the cable, and the second layer 30 makes it possible to ensure the continuity of the electrical insulation, as seen in FIG. 2.

After having wrapped the conductor cable with the two layers of ceramic sheathing 28 and 30, said cable is formed into windings according to means known in the state of the art. Then, the windings thus obtained from the conductor cable, consisting of the precursor wrapped in the ceramic sheath, are subjected to a heat treatment in a neutral gas such as argon.

This treatment includes a slow rise in temperature, at a rate close to 6° C. per hour, up to a temperature of 660° C., then a plateau stage at 660° C. for 240 hours, then a slow cooling to ambient temperature (20° C. to 23° C.) inside the treatment oven chamber.

This treatment enables the reaction of the precursor cable and the obtainment of a Nb₃Sn superconducting material having the desired properties.

During this heat treatment, a neutral gas circulates continuously inside the oven. The use of an inert atmosphere such as this during the heat treatment makes it possible to prevent harmful reactions between the Nb₃Sn precursor and the atmospheric oxygen, which may produce various metallic oxides capable of diminishing the properties of the superconductor formed.

The use of a temperature of 660° C. in a neutral gas is a significant constraint in producing a suitable ceramic insulation.

As a matter of fact, the glass frit used in the example of the invention has a melting point of 540° C. Therefore, it melts during the heat treatment necessary to the formation of the Nb₃Sn superconductor (during the course of which the temperature is maintained at 660° C.) and, after cooling to ambient temperature, thereby provides the electrical insulation and mechanical cohesion required by the applications of the invention, such as the formation of superconducting windings.

During operation of the superconducting electromagnets, each winding is cooled to the temperature of liquid helium (4.2 K at atmospheric pressure) or to that of superfluid helium (a temperature lower than 2.1 K at reduced pressure), in order to render superconductive the Nb₃Sn alloy constituting the conductor with which the winding cable is formed.

When an excitation current passes through the electromagnet, significant Lorentz forces appear in each winding. The mechanical cohesion provided by the ceramic insulation facilitates handling of the windings following the heat treatment and makes it possible to withstand the stresses produced by the operation of the electromagnet under intense magnetic fields.

Any other clay of the smectite group may be used in the invention, in place of the montmorillonite.

Moreover, it is possible to practice the invention using conductors other than a Nb₃Sn precursor, for example:
a Nb₃Al precursor or
a precursor of a copper oxide-based superconductor, such as YBa₂Cu₃O₇, Bi₂Sr₂CaCu₂O₂ or Bi₂Sr₂Ca₂Cu₃O₁₀, or
a metal that is not superconducting, e.g., copper, or
any conductor, including a superconductor that tolerates the heat treatment to which the ceramic precursor is subjected.

The invention applies, in particular:
to the manufacture of small, compact superconducting solenoids, devoid of any metal structuring elements, used primarily at low temperatures,
to the manufacture of windings for superconducting rotating electrical machines,
to the manufacture of windings for non-superconducting rotating electrical machines, designed to operate at temperatures greater than 300° C., by using conventional conductors, and
to the electrical insulation of conductor cables having to withstand high temperatures for a certain period of time, without releasing any harmful vapors in the event of a fire.

Let us now consider the rheological behavior of two particular ceramic suspensions that can be used in the invention.

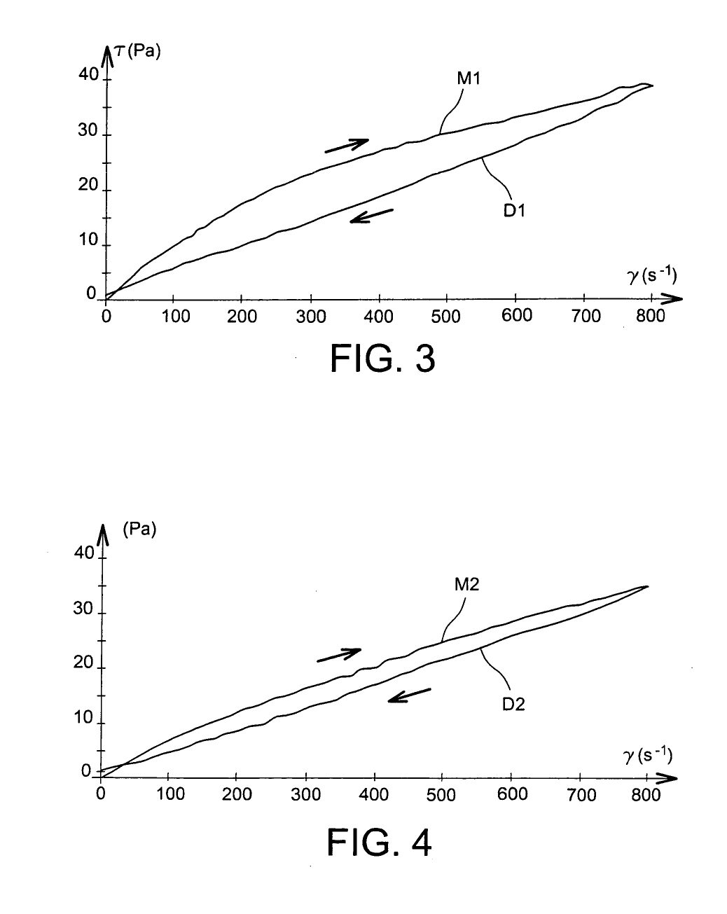

Reference will be made to FIGS. 3 and 4, which show the consistency curves for two ceramic suspensions having different compositions: FIG. 3 corresponds to a first composition and FIG. 4 to a second composition, which is different from the first.

Each of these consistency curves shows the variations in stress τ (expressed in Pa) in relation to the shear rate γ (expressed in s⁻¹).

The behavior is not of the Newtonian type, the mean viscosities of the two compositions being close to each other, around 45 mPa·s, but only the first composition (FIG. 3) provides an adequate deposit on the glass tape.

This difference is explained by the variation in the thixotropic behavior of the two suspensions. As a matter of fact, the two downward curves D1 and D2 are equivalent but, in the case of the upward curves M1 and M2, the first composition has a more shear-thinning behavior, which results in a higher degree of thixotropy.

The slow speed at which the glass tape circulates through the ceramic suspension creates low shear rates. Thus, during the impregnation phase, the experimental conditions are such that the rheological behavior corresponds to the start of the consistency curves.

The composition of the two suspensions is provided below in Table I. The clay used for the two suspensions is montmorillonite marketed by the company Arvel SA, under the name Expans.

TABLE I

| | Clay | Glass frit | Water |
|---|---|---|---|
| | (% by weight) | (% by weight) | (% by weight) |
| Suspension 1 | 11.5 | 46 | 42.5 |
| Suspension 2 | 10 | 50 | 40 |

1. A method for manufacturing an electrically insulating and mechanically structuring sheath on an electrical conductor, in particular a non-superconducting metal conductor, a superconducting metal conductor or a superconductor precursor conductor, the method being characterized in that it comprises the steps of:
forming a ceramic precursor in the form of a fluid solution, said ceramic precursor being a liquid consisting of a solution containing water, glass frit and a suspension of clay in water, without any organic element;
forming a coating for the conductor with said ceramic precursor; and
heat-treating said coating, said heat treatment being capable of forming the ceramic from the ceramic precursor.

2. The method of claim 1, in which the clay is selected from the smectite group.

3. The method of claim 2, in which the clay is montmorillonite.

4. The method as claimed in claim 1, in which the solution comprises, in percent by weight, 35% to 50% water, 8% to 15% clay and 35% to 55% glass frit.

5. The method as claimed in claim 1, in which the conductor is a superconductor precursor, in particular Nb₃Sn, and a global heat treatment of said conductor provided with the coating is carried out, said global heat treatment being capable of forming the superconductor and the ceramic.

6. The method as claimed in claim 1, in which the conductor is made of either a non-superconducting metal or a superconducting metal, and a heat treatment of said conductor provided with the coating is carried out, said heat treatment being capable of forming the ceramic.

7. The method as claimed in claim 1, in which the step of forming the coating comprises a step of depositing the ceramic precursor on a fiber tape, then a step of arranging the tape provided with the ceramic precursor around the conductor.

8. The method of claim 7, in which the fibers are made of a material selected from among type E glass, type C glass, type R glass, type S2 glass, pure silica, an alumina and an aluminosilicate.

9. The method as claimed in claim 7, in which the fiber tape is first desized.

10. The method of claim 9, in which the fiber tape is first desized thermally or chemically.

11. The method as claimed in claim 1, in which the conductor provided with the coating is formed prior to the heat treatment step capable of forming the ceramic.

12. The method of claim 11, in which the conductor provided with the coating is wound prior to the heat treatment step capable of forming the ceramic.
